(19) United States
(12) Patent Application Publication
(10) Pub. No.: US 2025/0239493 A1
(43) Pub. Date: Jul. 24, 2025

(54) DEVICE CHIP MANUFACTURING METHOD AND WORKPIECE PROCESSING APPARATUS

(71) Applicant: DISCO CORPORATION, Tokyo (JP)

(72) Inventor: Kazuma SEKIYA, Tokyo (JP)

(21) Appl. No.: 19/021,439

(22) Filed: Jan. 15, 2025

(30) Foreign Application Priority Data
Jan. 22, 2024 (JP) 2024-007422

(51) Int. Cl. H01L 21/66; H01L 21/67; H01L 21/683; H01L 21/78

(52) U.S. Cl. CPC H01L 22/12; H01L 21/67092; H01L 21/6836; H01L 21/78

(57) ABSTRACT

A device chip manufacturing method is of dividing a workpiece that has a disc shape and in which a chamfered portion is formed along an outer peripheral edge and a plurality of division lines is set, along the division lines to dice the workpiece into device chips. The method includes: bonding a tape larger than an outer diameter of the workpiece to a front surface side or a back surface side of the workpiece; filling a gap between the chamfered portion formed on the outer peripheral edge of the workpiece and the tape, with a filling member; and after the filling, moving the workpiece and a cutting blade relative to each other to cut the workpiece along the division lines, and dividing the workpiece to be diced into the device chips.

### CROSS-REFERENCE TO RELATED APPLICATION(S)

The present application claims priority to and incorporates by reference the entire contents of Japanese Patent Application No. 2024-007422 filed in Japan on Jan. 22, 2024.

### BACKGROUND

The present disclosure relates to a device chip manufacturing method and a workpiece processing apparatus.

As a method of manufacturing a device chip, there is a known method of cutting a workpiece such as a semiconductor wafer along a plurality of division lines set on the workpiece so as to dice the workpiece into device chips. In such a method, for example, after a dicing tape is bonded to a workpiece, the workpiece is held on a chuck table via the dicing tape, and the chuck table is moved for processing feeding in a state where a lower end of a cutting blade rotating at a high speed is positioned between the dicing tape and a holding surface, thereby cutting the workpiece.

Here, when the plurality of division lines is set in a lattice shape, there will be end material chips each formed to have a substantially triangular shape or a substantially trapezoidal shape each having one curved side, in the vicinity of an outer peripheral edge of the workpiece. This end material chip is smaller in area compared with the device chip. When a chamfered portion is formed on the outer peripheral edge of the workpiece, cutting water easily enters between the workpiece and the dicing tape during cutting. This might lead to occurrence of a phenomenon referred to as die flying in which the end material chip peels off from the dicing tape and scatters during cutting, leading to a risk of damaging the device chip. To handle this, there has been proposed a method of suppressing the die flying from an end material chip by performing cutting work in a state where both surfaces of a workpiece are bound between tapes (see JP 2009-130315 A).

However, the above-described method has a necessity to peel off the tape divided into device sizes by processing, and thus has a problem of increased man-hours.

### SUMMARY

A device chip manufacturing method according to one aspect of the present disclosure is of dividing a workpiece that has a disc shape and in which a chamfered portion is formed along an outer peripheral edge and a plurality of division lines is set, along the division lines to dice the workpiece into device chips. The method includes: bonding a tape larger than an outer diameter of the workpiece to a front surface side or a back surface side of the workpiece; filling a gap between the chamfered portion formed on the outer peripheral edge of the workpiece and the tape, with a filling member; and after the filling, moving the workpiece and a cutting blade relative to each other to cut the workpiece along the division lines, and dividing the workpiece so as to be diced into the device chips.

A processing apparatus according to another aspect of the present disclosure includes: a holding table configured to hold, via a tape, a workpiece that has a disc shape and in which a chamfered portion is formed along an outer peripheral edge and the tape larger than an outer diameter of the workpiece is bonded to a front surface side or a back surface side; a processing unit including a cutting blade that performs cutting work on the workpiece held on the holding table; a moving unit configured to move the holding table and the processing unit relative to each other; and a filling member supply unit configured to fill a gap between the chamfered portion formed on the outer peripheral edge of the workpiece and the tape, with a filling member.

### BRIEF DESCRIPTION OF THE DRAWINGS

FIG. 1 is a perspective view of a workpiece to be processed by a workpiece processing method according to an embodiment;

FIG. 2 is a side view of the workpiece illustrated in FIG. 1;

FIG. 3 is a flowchart illustrating a flow of the workpiece processing method according to the embodiment;

FIG. 4 is a perspective view illustrating a state of a tape bonding step illustrated in FIG. 3;

FIG. 5 is a partial cross-sectional side view illustrating a state after the tape bonding step illustrated in FIG. 3;

FIG. 6 is a perspective view illustrating a configuration example of a processing apparatus according to the embodiment;

FIG. 7 is a partial cross-sectional side view illustrating a state of a detection step illustrated in FIG. 3;

FIG. 8 is a plan view of the workpiece for illustrating the detection step illustrated in FIG. 3;

FIG. 9 is a partial cross-sectional side view illustrating a state of a filling step illustrated in FIG. 3;

FIG. 10 is a partial cross-sectional side view illustrating a state after the filling step illustrated in FIG. 3; and

FIG. 11 is a perspective view illustrating a state of a cutting step illustrated in FIG. 3.

### DETAILED DESCRIPTION

A mode (embodiment) for carrying out the present disclosure will be described in detail with reference to the drawings. The present invention is not limited by the description in the following embodiments. In addition, the constituent elements described below include elements easily conceivable by those skilled in the art and elements that are substantially the same. Furthermore, the configurations described below can be appropriately combined with each other. In addition, various omissions, substitutions, or alterations in the configuration can be made without departing from the scope and spirits of the present invention.

### EMBODIMENT

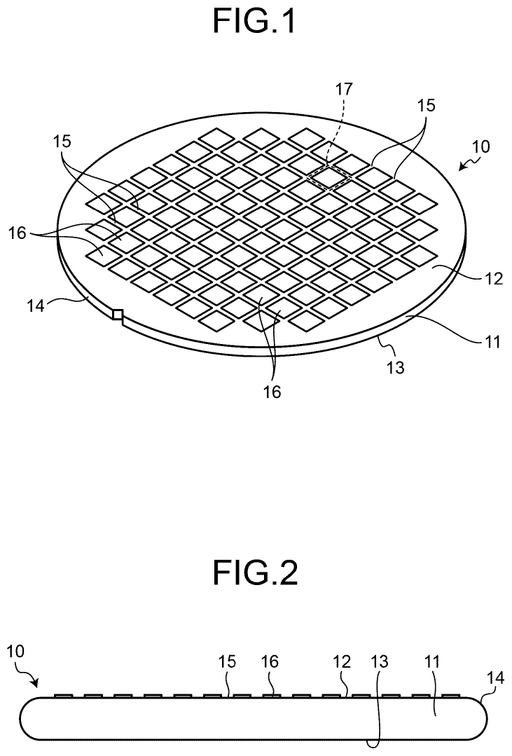

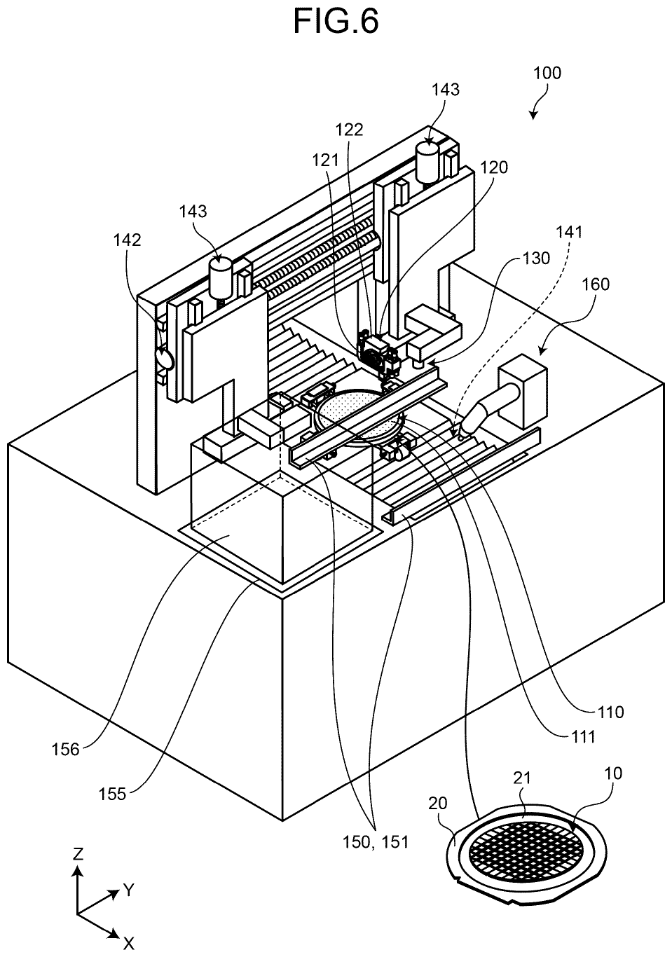

A processing method of a workpiece 10 and a processing apparatus 100 according to an embodiment of the present disclosure will be described with reference to the drawings. The processing method of the workpiece 10 of the embodiment is a method for dicing the workpiece 10 illustrated in FIGS. 1 and 2 into device chips 17 by the processing apparatus 100 illustrated in FIG. 6, in other words, a device ship manufacturing method.

### Workpiece 10

First, a configuration of the workpiece 10 to be processed by the processing method of the workpiece 10 according to the embodiment of the present disclosure will be described. FIG. 1 is a perspective view of the workpiece 10 to be processed by the processing method of the workpiece 10 according to the embodiment. FIG. 2 is a side view of the workpiece 10 illustrated in FIG. 1.

The workpiece 10 illustrated in FIGS. 1 and 2 is a wafer such as a disc-shaped semiconductor device wafer and an optical device wafer using a material such as silicon (Si), sapphire (Al2O3), gallium arsenide (GaAs), silicon carbide (SiC), and lithium tantalate (LiTaO3) as a substrate 11. As illustrated in FIG. 2, there is a chamfered portion 14 formed along an outer peripheral edge of the workpiece 10 such that the center in the thickness direction protrudes to the outermost peripheral side and has a cross-sectional arc shape from a front surface 12 to a back surface 13 of the substrate 11.

The workpiece 10 includes: a plurality of division lines 15 set in a lattice shape; and a device 16 formed on a front surface 12 of a region defined by the division lines 15 intersecting each other. The device 16 is, for example, an integrated circuit such as an Integrated Circuit (IC) or a Large Scale Integration (LSI), or an image sensor such as a Charge Coupled Device (CCD) and a Complementary Metal Oxide Semiconductor (CMOS).

The workpiece 10 is divided into individual devices 16 along the plurality of division lines 15 so as to be diced into the device chips 17. The device chip 17 has a square shape in the embodiment, but may have a rectangular shape.

### Processing Method of Workpiece 10

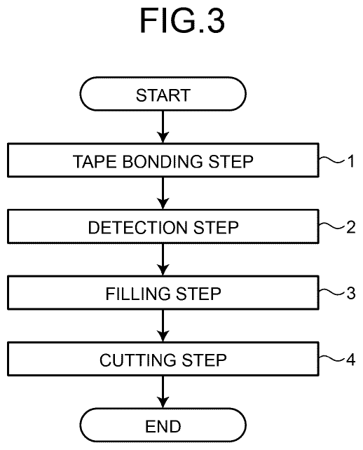

Next, a processing method of the workpiece 10 according to the embodiment of the present disclosure will be described. FIG. 3 is a flowchart illustrating a flow of the processing method of the workpiece 10 according to the embodiment. The processing method of the workpiece 10 includes a tape bonding step 1, a detection step 2, a filling step 3, and a cutting step 4. The detection step 2 may be omitted.

### Tape Bonding Step 1

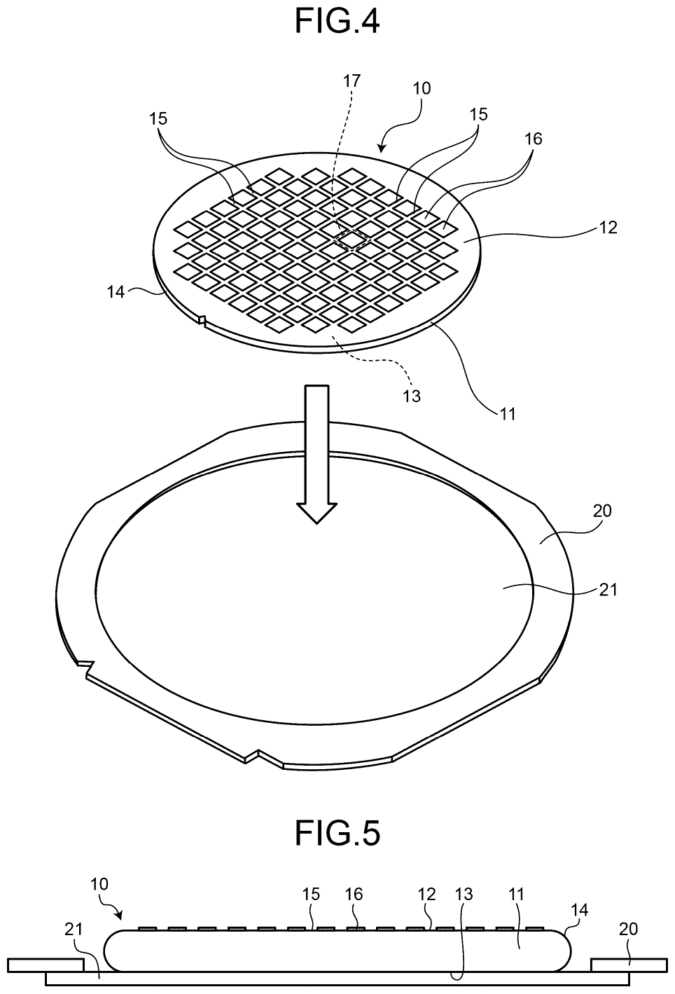

FIG. 4 is a perspective view illustrating one state of the tape bonding step 1 illustrated in FIG. 3. FIG. 5 is a partial cross-sectional side view illustrating a state after the tape bonding step 1 illustrated in FIG. 3. The tape bonding step 1 is a step of bonding a tape 21 (dicing tape) larger than the outer diameter of the workpiece 10 to the front surface 12 side or the back surface 13 side of the workpiece 10. In the tape bonding step 1 of the embodiment, the tape 21 is bonded to the back surface side of a frame 20 having an annular shape and the back surface 13 side of the workpiece 10, with the workpiece 10 positioned inside the opening of the frame 20.

The frame 20 is an annular plate member formed with metal or resin and having an opening larger than the outer diameter of the workpiece 10. The tape 21 has a sheet shape having an outer diameter larger than the opening of the frame 20, and is bonded to the back surface side of the frame 20 so as to cover the opening of the frame 20. The tape 21 may include, for example, a base material layer formed with a stretchable synthetic resin and an adhesive layer laminated on the base material layer and formed with a stretchable and adhesive synthetic resin, or may be formed with a thermoplastic resin instead of the adhesive layer.

The workpiece 10 is positioned at a predetermined position of the opening of the frame 20. The front surface 12 side or the back surface 13 side of the workpiece 10 is bonded to the tape 21, allowing the workpiece 10 to be fixed to the frame 20 and the tape 21. At this time, on the side of the surface (in the embodiments, the back surface 13) bonded to the tape 21, there is a gap occurring between the chamfered portion 14 formed on the outer peripheral edge of the workpiece 10 and the tape 21 due to the roundness of the chamfered portion 14. The workpiece 10 is transferred and processed in a state of being supported by the annular frame 20 and the tape 21.

### Processing Apparatus 100

Here, a configuration example of the processing apparatus 100 according to the embodiment of the present disclosure will be described. FIG. 6 is a perspective view illustrating a configuration example of the processing apparatus 100 according to the embodiment. The processing apparatus 100 is a cutting apparatus that performs cutting work on the workpiece 10. In the processing method of the workpiece 10, the processing apparatus 100 performs a detection step 2, a filling step 3, and a cutting step 4.

The processing apparatus 100 includes a holding table 110, a cutting unit 120, a detection unit 130, an X-axis moving unit 141, a Y-axis moving unit 142, a Z-axis moving unit 143, a transfer unit 150, a cassette placing base 155, and a filling member supply unit 160. As illustrated in FIG. 6, the processing apparatus 100 is a processing apparatus (cutting apparatus) including two sets of cutting units 120, that is, an apparatus also referred to as a two-spindle dicer or a facing dual type apparatus.

The holding table 110 holds the disc-shaped workpiece 10 to which the tape 21 is bonded, by a holding surface 111 via the tape 21. The holding table 110 includes, for example, a disc-shaped frame body having a recess, and a disc-shaped suction portion fitted in the recess. The suction portion of the holding table 110 is formed with a material such as porous ceramic having a large number of porous holes, and is connected to a vacuum suction source (not illustrated) via a vacuum suction path (not illustrated). The upper surface of the suction portion of the holding table 110 is the holding surface 111 on which the workpiece 10 is placed and which sucks and holds the placed workpiece 10 by a negative pressure introduced from the vacuum suction source. The holding table 110 is movable in the X-axis direction parallel to the horizontal direction by the X-axis moving unit 141. The holding table 110 is rotatable around a Z axis parallel to the vertical direction and orthogonal to an XY plane by a rotary drive source (not illustrated).

The cutting unit 120 is a processing unit that performs cutting work on the workpiece 10 held on the holding table 110. The cutting unit 120 includes a cutting blade 121, a spindle 122 to which the cutting blade 121 is rotatably mounted, and a cutting liquid supply unit that supplies cutting liquid to the cutting blade 121 and a processing point. The cutting blade 121 perform cutting work on the workpiece 10 held on the holding table 110.

The spindle 122 is rotatable around an axis parallel to the horizontal direction and parallel to the Y-axis direction orthogonal to the X-axis direction, and rotatably supports the cutting blade 121 attached to the tip of the spindle 122 around the axis parallel to the Y-axis direction. The cutting unit 120 is movable in the Y-axis direction and the Z-axis direction by the Y-axis moving unit 142 and the Z-axis moving unit 143, respectively.

Using the cutting blade 121, which moves by the X-axis moving unit 141 in the X-axis direction being the processing feeding direction relative to the workpiece 10 on the holding table 110 and to which the rotating operation about the axis parallel to the Y-axis direction is applied by the spindle 122, the cutting unit 120 cuts the workpiece 10 along the division lines 15, for example.

In the embodiment, the detection unit 130 is an imaging unit including an imaging element that images the workpiece 10 held on the holding table 110. The imaging element includes a CCD imaging element or a CMOS imaging element, for example. In the embodiment, the detection unit 130 is fixed adjacent to the cutting unit 120 and moves integrally with the cutting unit 120.

The detection unit 130 images the front surface 12 of the workpiece 10 held on the holding table 110 to obtain an image for performing alignment to set the workpiece 10 and the cutting unit 120 in correct relative positions, and then outputs the obtained image to the control unit of the processing apparatus 100. The detection unit 130 detects the plurality of division lines 15 set in the workpiece 10 held on the holding table 110, and detect a region to be an end material chip 18 (refer to FIG. 8 described below) which is an end material of the device chip 17, in the outer peripheral region of the workpiece 10.

The X-axis moving unit 141, the Y-axis moving unit 142, and the Z-axis moving unit 143 are moving unit that moves the holding table 110, the cutting unit 120, and the detection unit 130 relative to each other in the X-axis direction, the Y-axis direction, and the Z-axis direction, respectively. In the embodiment, the X-axis moving unit 141 moves the holding table 110 relative to the cutting unit 120 and the detection unit 130 in the X-axis direction. The X-axis moving unit 141 moves the holding table 110 between a loading/unloading region where the workpiece 10 is loaded into or unloaded from the holding table 110, a supply region where the filling member 30 is supplied by the filling member supply unit 160, and a processing region to undergo cutting work by the cutting unit 120.

In the embodiment, the Y-axis moving unit 142 and the Z-axis moving unit 143 move the cutting unit 120 and the detection unit 130 relative to the holding table 110 in the Y-axis direction and the Z-axis direction, respectively. The X-axis moving unit 141, the Y-axis moving unit 142, and the Z-axis moving unit 143 are known ball screw mechanisms each having a motor, a ball screw, and a guide.

In the embodiment, the transfer unit 150 includes, for example, a pair of rails 151, and a first transfer arm and a second transfer arm (not illustrated). The first transfer arm transfers the workpiece 10 between the cassette 156 placed on the cassette placing base 155 and the pair of rails 151. The second transfer arm transfers the workpiece 10 between the pair of rails 151 and the holding table 110. The pair of rails 151 can approach or separate from each other while maintaining a state of being parallel to each other, making possible to hold the workpiece 10 between the pair of rails 151 via the frame 20.

The cassette placing base 155 is a placing base on which a cassette 156, which is a container for accommodating a plurality of workpieces 10, is placed, and lifts and lowers the placed cassette 156 in the Z-axis direction.

The filling member supply unit 160 is a unit that fills the gap between the tape 21 and the chamfered portion 14 formed on the outer peripheral edge of the workpiece 10 held on the holding table 110 via the tape 21, with the filling member 30. The filling member supply unit 160 includes: a supply source that stores the filling member 30; a nozzle that discharges the filling member 30 in a predetermined direction; a flow path and a delivery pump that supply the filling member 30 from the supply source toward the opening of the nozzle. The filling member supply unit 160 may be configured to be movable between a supply position where the nozzle is positioned on the workpiece 10 held on the holding table 110 and a non-supply position where the nozzle is retracted.

The filling member 30 is a member that is liquid at the time of supply and is cured after being filled in the gap between the chamfered portion 14 and the tape 21, and includes a hot melt adhesive or a liquid resin such as a UV curable resin, for example. The filling member 30 may contain abrasives. When the filling member 30 is a UV curable resin, the processing apparatus 100 may include a UV emission unit that emits UV light to the supplied filling member 30. The UV emission unit is provided, for example, on the holding table 110 with the holding surface 111 formed with a transparent member such as glass, and a light source is disposed below the holding surface 111.

### Detection Step 2

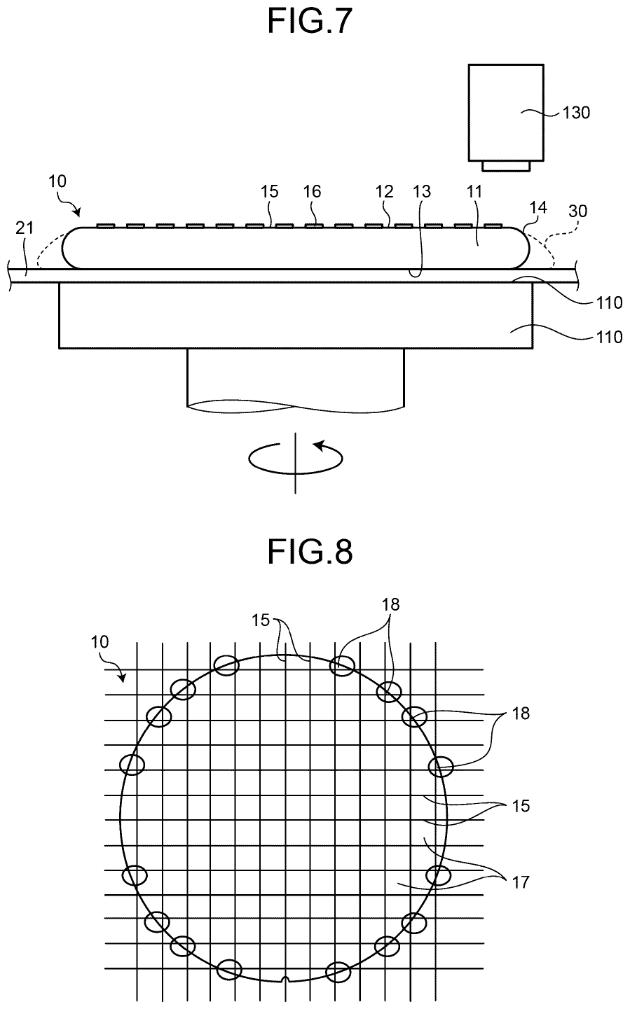

FIG. 7 is a partial cross-sectional side view illustrating a state of a detection step 2 illustrated in FIG. 3. FIG. 8 is a plan view of the workpiece 10 for illustrating the detection step 2 illustrated in FIG. 3. The detection step 2 is performed before the filling step 3. The detection step 2 is a step of detecting a region to be an end material chip 18 which is an end material of the device chip 17 formed in the cutting step 4 described below.

The cassette 156 containing the workpiece 10 to which the tape 21 is bonded in the tape bonding step 1 is carried into the cassette placing base 155 of the processing apparatus 100. The workpiece 10 is sent out from the cassette 156 one by one by the transfer unit 150, and is held on the holding table 110 via the tape 21. The workpiece 10 held on the holding table 110 is moved by the X-axis moving unit 141 to an imaging region of the detection unit 130.

As illustrated in FIG. 7, in the detection step 2, the detection unit 130 captures an image of the front surface 12 side of the workpiece 10. Processing such as image recognition is performed on the captured image, thereby detecting the plurality of division lines 15 set on the workpiece 10. In the detection step 2, the region to be the end material chip 18 is detected from the outer peripheral edge of the workpiece 10 and the plurality of division lines 15.

As illustrated in FIG. 8, the region to be the end material chip 18 is an outer peripheral region not including the device 16 and is to be an end material when the workpiece 10 undergoes cutting work along the division lines 15 and diced into the device chips 17 in the cutting step 4 described below. This region particularly indicates a region smaller than a predetermined area, having a shape such as a substantially triangular shape or a substantially pedestal shape, each with one curved side. Here, the predetermined area indicates an area of 70% or less of the area of the normal device chip 17. Practically, for example, it is allowable to define the region where the intersection of the division lines 15 exists within a predetermined distance (for example, 1 mm) from the outer peripheral edge of the workpiece 10, as the end material chip 18. In other words, the region to be the end material chip 18 is a region that can be peeled off and scattered from the tape 21 at the time of cutting work.

### Filling Step 3

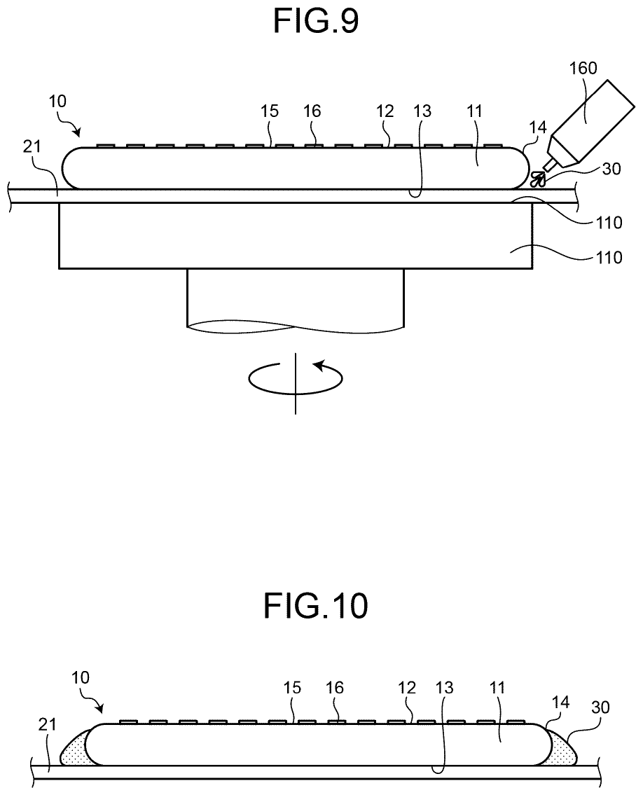

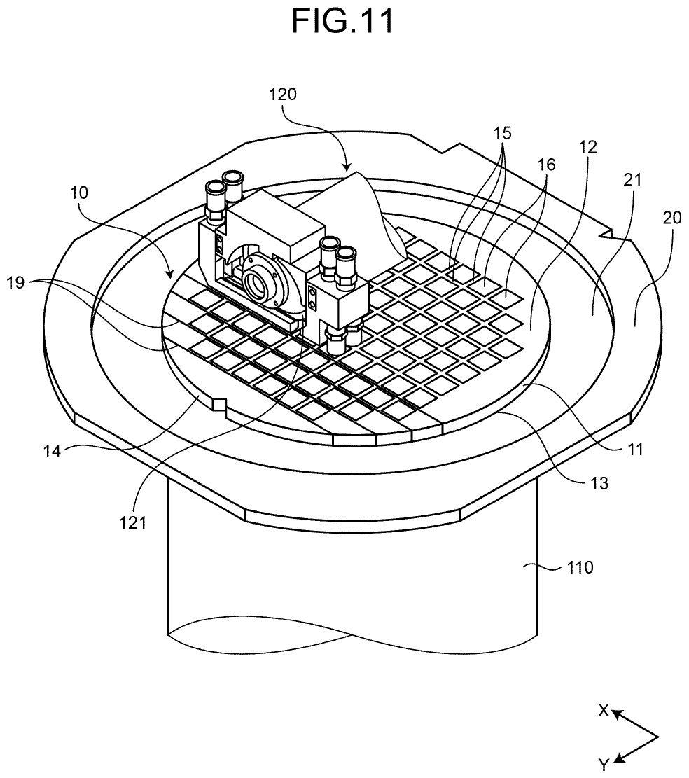

FIG. 9 is a partial cross-sectional side view illustrating a state of a filling step 3 illustrated in FIG. 3. FIG. 10 is a partial cross-sectional side view illustrating a state after the filling step 3 illustrated in FIG. 3. The filling step 3 is a step of filling a gap between the chamfered portion 14 formed on the outer peripheral edge of the workpiece 10 and the tape 21, with the filling member 30.

The filling step 3 moves the workpiece 10 held on the holding table 110 via the tape 21 to the supply region of the filling member supply unit 160 by the X-axis moving unit 141. As illustrated in FIG. 9, in the filling step 3, the tip of the nozzle of the filling member supply unit 160 is directed to the gap between the chamfered portion 14 and the tape 21, and the holding table 110 is rotated about the axis with the filling member 30 being supplied, so as to fill the gap between the chamfered portion 14 and the tape 21 with the filling member 30.

When the detection step 2 is performed, the filling step 3 supplies the filling member 30 intermittently from the filling member supply unit 160, so as to fill only the region to be the end material chip 18 detected in the detection step 2 with the filling member 30. When omitting the detection step 2, the filling step 3 supplies the filling member 30 continuously from the filling member supply unit 160, so as to fill the filling member 30 along the entire circumference of the outer peripheral edge of the workpiece 10. After the supplied filling member 30 is cured, the cutting step 4 is performed.

### Cutting Step 4

FIG. 11 is a perspective view illustrating a state of cutting step 4 illustrated in FIG. 3. The cutting step 4 is performed after the filling step 3. The cutting step 4 is a step of cutting the workpiece 10 along the division lines 15 to divide the workpiece 10 to be diced into the device chip 17.

The cutting step 4 first uses the X-axis moving unit 141 to move the workpiece 10 held on the holding table 110 via the tape 21 to the processing region of the cutting unit 120. The detection unit 130 images the workpiece 10 to detect the division lines 15. When the division lines 15 are detected, alignment is performed to set the division lines 15 of the workpiece 10 and the cutting blade 121 in correct relative positions.

The cutting step 4 next starts the supply of cutting liquid toward the processing point by the cutting blade 121, and also starts the rotation of the spindle 122. Next, while the holding table 110 is moved for processing feeding in the X-axis direction by the X-axis moving unit 141, the cutting unit 120 is brought into cutting to a predetermined depth by the Z-axis moving unit 143 until the cutting edge of the cutting blade 121 reaches the tape 21. This procedure forms a cutting groove 19 over the entire region of the workpiece 10 in the thickness direction. When the workpiece 10 is divided along one division line 15, indexing is performed in the Y-axis direction such that the cutting blade 121 is positioned in the adjacent division line 15, and the workpiece 10 is similarly divided along the division line 15.

In this manner, the cutting step 4 moves the workpiece 10 held on the holding table 110 and the cutting blade 121 relative to each other, and cuts the workpiece 10 along all the division lines 15, thereby dicing the workpiece 10 into the device chips 17. At this time, the filling member 30 suppress intrusion of the cutting water onto the back surface 13 side, and maintains the state in which the end material chip 18 is stuck to the tape 21. In addition, in a case where the filling member 30 includes abrasives, the grindstone of the cutting blade 121 of the cutting blade can be sharpened when the cutting blade 121 cuts the filling member 30.

As described above, in the processing method and the processing apparatus 100 of the workpiece 10 of the embodiment, the filling member 30 is filled in the gap between the chamfered portion 14 formed on the outer peripheral edge of the workpiece 10 and the tape 21, and the cutting work is performed in this state. This configuration has an effect of suppressing peeling and scattering of the end material chip 18 due to intrusion of cutting water into the gap, leading to a lowered risk of breakage of the device 16.

When the filling member 30 is filled over the entire circumference of the workpiece 10, it is possible to enhance the effect of suppressing the intrusion of cutting water. On the other hand, when the detection step 2 is performed to fill the filling member 30 only in a region where peeling and scattering of the end material chip 18 are likely to occur, it is possible to save the filling member 30.

The detection step 2 is not limited to the method of recognizing the end material chip 18 by the technique such as image processing as in the embodiment. The end material chip 18 may be recognized from the size of the workpiece 10, the size of the device chip 17, the position of an indicator such as an orientation flat or a notch indicating the crystal orientation.

The detection unit 130 may be disposed adjacent to the filling member supply unit 160. In this case, the unit is provided separately from the imaging unit for aligning the workpiece 10 and the cutting unit 120 with each other. In addition, in the filling step 3, the outer peripheral edge of the workpiece 10 may be detected and aligned with the filling position after the workpiece 10 is transferred to the supply region and before the supply of the filling member 30 is started. When the detection unit 130 is disposed adjacent to the filling member supply unit 160, the workpiece 10 is transferred from the cassette 156 to the supply region to perform the detection step 2 and the filling step 3, and then the workpiece 10 is transferred to the processing region to undergo the cutting step 4 after alignment using an imaging unit different from the detection unit 130. This makes it possible to shorten the movement distance of the holding table 110 and the workpiece 10.

According to the present disclosure, it is possible to suppress die flying of an end material chip to lower the risk of breakage of a device and also reduce man-hours.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A device chip manufacturing method of dividing a workpiece that has a disc shape and in which a chamfered portion is formed along an outer peripheral edge and a plurality of division lines is set, along the division lines to dice the workpiece into device chips, the method comprising:
bonding a tape larger than an outer diameter of the workpiece to a front surface side or a back surface side of the workpiece;
filling a gap between the chamfered portion formed on the outer peripheral edge of the workpiece and the tape, with a filling member; and
after the filling, moving the workpiece and a cutting blade relative to each other to cut the workpiece along the division lines, and dividing the workpiece so as to be diced into the device chips.

2. The device chip manufacturing method according to claim 1, further comprising
before the filling, detecting a region to be an end material chip, the end material chip being an end material of the device chip formed at the cutting, wherein
the filling includes filling the region to be the end material chip detected at the detecting with the filling member.

3. A processing apparatus comprising:
a holding table configured to hold, via a tape, a workpiece that has a disc shape and in which a chamfered portion is formed along an outer peripheral edge and the tape larger than an outer diameter of the workpiece is bonded to a front surface side or a back surface side;
a processing unit including a cutting blade that performs cutting work on the workpiece held on the holding table;
a moving unit configured to move the holding table and the processing unit relative to each other; and
a filling member supply unit configured to fill a gap between the chamfered portion formed on the outer peripheral edge of the workpiece and the tape, with a filling member.

4. The processing apparatus according to claim 3, further comprising a detection unit configured to detect a plurality of division lines set for the workpiece to dice the workpiece held on the holding table into device chips, and a region to be an end material chip, the end material chip being an end material of the device chip in an outer peripheral region of the workpiece.
